(19) United States
(12) Patent Application Publication
(10) Pub. No.: US 2001/0011739 A1
(43) Pub. Date: Aug. 9, 2001

(54) Ferroelectric random access memory device

(76) Inventor: Eung-Youl Kang, Ichon-Shi (KR)

Correspondence Address: JACOBSON, PRICE, HOLMAN & STERN, PROFESSIONAL LIMITED LIABILITY COMPANY, 400 Seventh Street, N.W., Washington, DC, 20004, US

(21) Appl. No.: 09/746,459

(22) Filed: Dec. 26, 2000

(30) Foreign Application Priority Data
Dec. 28, 1999 (KR) 1999-64055

(51) Int. Cl. H01L 21/00; H01L 29/76; H01L 29/94; H01L 31/062; H01L 31/113; H01L 31/119

(52) U.S. Cl. 257/295; 438/3

(57) ABSTRACT

A ferroelectric memory cell for use in a ferroelectric random access memory (FeRAM) device that includes a first active area incorporating therein a gate of a depletion mode transistor, a second active area adjacent to the first active area and incorporating therein a gate of an enhancement mode transistor, a word line coupled to the gate of the depletion mode transistor and the gate of the enhancement mode transistor, and a ferroelectric capacitor coupled to a drain of the enhancement mode transistor, for storing data.

### FIELD OF THE INVENTION

The present invention relates to a semiconductor device and, more particularly, to a ferroelectric random access (FeRAM) device provided with a bit line with active areas of depletion mode transistors, thereby obtaining a FeRAM device with a high integration.

### DESCRIPTION OF THE PRIOR ART

With the recent progress of film deposition techniques, applications of a nonvolatile memory cell using a ferroelectric thin film have increasingly been developed. This nonvolatile memory cell is a high-speed rewritable nonvolatile memory cell utilizing the high-speed polarization/inversion and the residual polarization of the ferroelectric capacitor thin film.

Therefore, a ferroelectric random access memory (FeRAM) where a capacitor thin film with ferroelectric properties such as strontium bismuth tantalate (SBT) and lead zirconate titanate (PZT) is increasingly used for a capacitor, because it assures a low-voltage and high-speed performance, and does not require periodic refresh to prevent loss of information during standby intervals like a dynamic random access memory (DRAM).

Since a ferroelectric material has a dielectric constant ranging from a value of hundreds to thousands, and stabilized residual polarization property at room temperature, such material is being applied to the non-volatile memory device as the capacitor thin film. When employing the ferroelectric capacitor thin film in the non-volatile memory device, information data are stored by polarization of dipoles when an electric field is applied thereto. Even if the electric field is removed, the residual polarization still remains so that the information data, i.e., 0 or 1, can be stored.

Generally, the FeRAM device is fabricated by means of two methods. According to the first method, a word line is made of a polysilicon and a bit line is formed using a metal and, according to the second method, the word line and the bit line are both made of the polysilicon. The first method is utilized for manufacturing a device with a low integration, wherein a design rule between the metal bit line and a metal interconnection that connects a storage node to a drain region mainly affects a cell area. When employing the second method, the design rule between the polysilicon bit line and the metal interconnection is not restricted in comparison with that of the first method. However, two polysilicon layers should be formed in order to obtain the word line and the bit line, thereby adding a manufacturing step and increasing cost.

In a memory cell structure of a conventional FeRAM device, because an active area is separated from the bit line, a bit line contact should be formed in order to apply data to the bit line. Therefore, it is necessary when securing space in the device to consider a size of the bit line contact, an overlap margin of the bit line contact and the active area, and an overlap margin of the contact and the word line. For example, if the size of the bit line contact is 1.0 μm , the overlap margin of the contact and the active area and that of the contact and the word line are 0.5 μm respectively, each cell needs the space of about 2 μm. Therefore, there is a limitation when implementing a high integration device in the conventional FeRAM structure in which the active area is separated from the bit line.

### SUMMARY OF THE INVENTION

It is, therefore, an object of the present invention to provide a ferroelectric random access memory (FeRAM) provided with a bit line with active areas of depletion mode transistors, thereby obtaining a FeRAM device with a high integration.

In accordance with one aspect of the present invention, there is provided a ferroelectric memory cell for use in a ferroelectric random access memory (FeRAM) device, the ferroelectric memory cell comprising a first active area incorporating therein a gate of a depletion mode transistor; a second active area adjacent to the first active area incorporating therein a gate of an enhancement mode transistor; a word line coupled to the gate of the depletion mode transistor and the gate of the enhancement mode transistor; and a ferroelectric capacitor coupled to a drain of the enhancement mode transistor, for storing data.

In accordance with another aspect of the present invention, there is provided a ferroelectric random access memory (FeRAM) device including a plurality of ferroelectric memory cells, comprising first active areas incorporating therein gates of depletion mode transistors; second active areas adjacent to the first active areas incorporating therein gates of enhancement mode transistors; word lines coupled to the gates of the depletion mode transistors and the gates of the enhancement mode transistors; and ferroelectric capacitors coupled to drains of the enhancement mode transistors, for storing data.

### BRIEF DESCRIPTION OF THE DRAWINGS

The above and other objects and features of the present invention will become apparent from the following description of the preferred embodiment given in conjunction with the accompanying drawings, in which:

FIG. 1 is a layout of a ferroelectric random access memory (FeRAM) device in accordance with a preferred embodiment of the present invention; and

FIG. 2 is a circuit diagram of the FeRAM device in accordance with the preferred embodiment of the present invention.

### DETAILED DESCRIPTION OF THE PREFERRED EMBODIMENTS

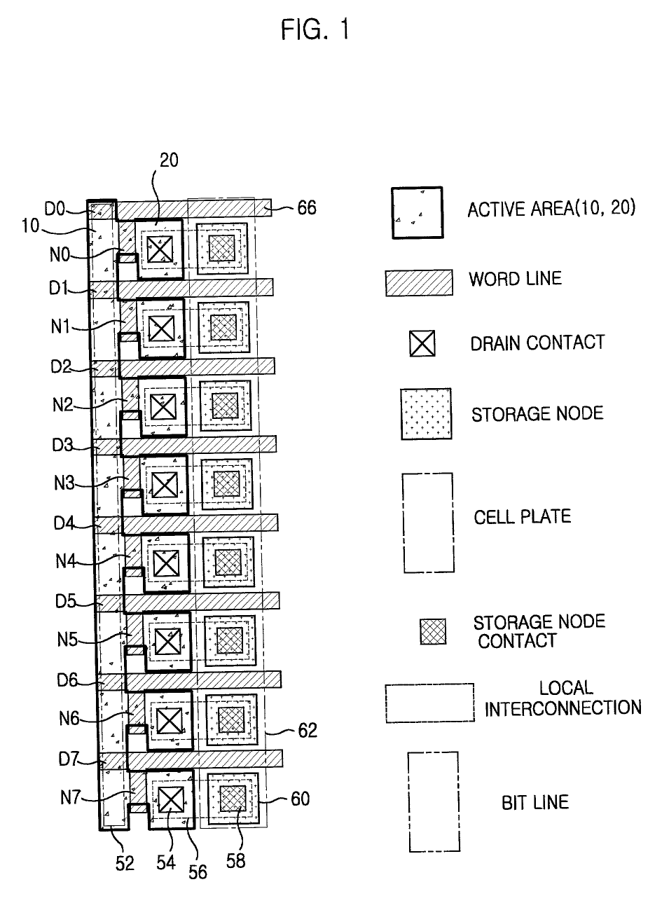

Referring to FIG. 1, there is provided a layout of a ferroelectric random access memory (FeRAM) device in accordance with a preferred embodiment of the present invention. As shown, a memory cell of the FeRAM device includes a ferroelectric capacitor, an enhancement mode transistor (N0, N1) for applying data stored in the ferroelectric capacitor to a bit line, a word line 66 coupled to the enhancement mode transistor (N0, N1) and a bit line 52 for transmitting the data applied from the word line 66 into a sense amplifier. The memory cell includes a first active area 10 incorporating therein a gate of the depletion mode transistor (D0, D1) disposed on an upper portion of the first active area 10, a second active area 20 incorporating therein a gate of the enhancement mode transistor (N0, N1) disposed on an upper portion of the second active area 20, and word line 66 which is connected to the gate of the depletion mode transistor (D0, D1) and the gate of the enhancement mode transistor (N0, N1). The ferroelectric capacitor is connected to a drain of the enhancement mode transistor (N0, N1). The first and the second active areas 10, 20 are n-types and they are adjacent to each other in this embodiment of the present invention. A cell plate 62 of the ferroelectric capacitor is parallel with the bit line 52.

Reference numerals 54, 56, 58, 60 denote a drain contact of the enhancement mode transistor, a local interconnection, a storage node contact, a storage node, respectively. The local interconnection 56 connects the drain contact 54 of the enhancement mode transistor (N0, N1) to the ferroelectric capacitor.

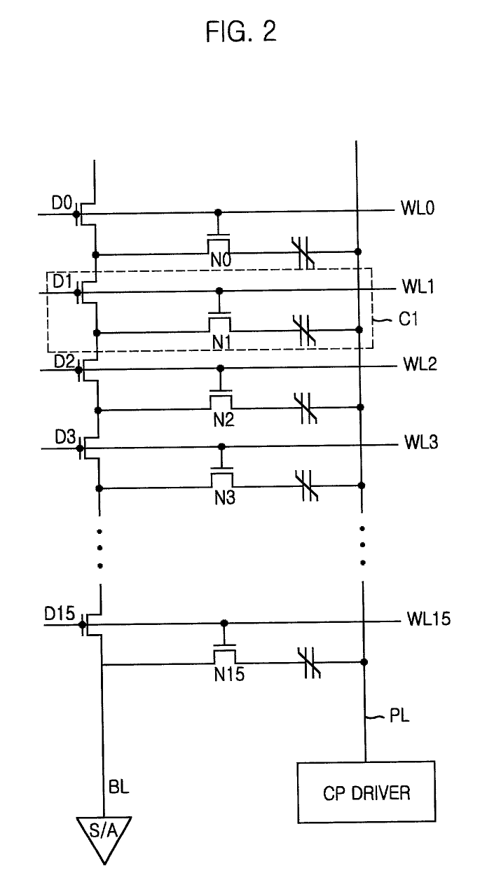

Referring to FIG. 2, the operating mechanism of the FeRAM device of the present invention is illustrated in more detail. In a stand-by mode, whole word lines (WL0, WL1 ) are maintained in low level and are also maintained in the low level during bit line precharge. If a specific word line, e.g., WL1, is set to a high level and a plate line is set to the high level simultaneously, the depletion mode transistor D1 and the enhancement mode transistor N1 are turned on so that the data are transmitted into a sense amplifier through the bit line. Meanwhile, the other enhancement mode transistors are turned off so that the data cannot be applied to the bit line. It is noted that the depletion mode transistors (D0, D1) are always turned on even though each word line is set to high or low level, whereby the data applied by the specific word line can be applied to the bit line.

The present invention provides, but id not limited to, a 16 cell array. For example, it is possible to implement 32, 64 or 128 cell arrays. At this time, a metal contact may be formed every 16 bits or 32 bits for lowering the resistance of the bit line so that the data applied to the bit line is transmitted through the bit line and the metal contact.

The operating mechanism of the FeRAM device of the present invention is similar to that of a conventional FeRAM or DRAM device. Therefore, a detailed description of the operating mechanism will be abbreviated here. Significantly, in the present invention, the depletion mode transistors (D0, D1) are formed on the first active area and each first active area is coupled to other first active areas, thereby forming the bit line.

The depletion mode transistors (D0, D1 . . . ) and the enhancement mode transistors (N0, N1 . . . are formed by either of two methods as follows. The first method begins with exposing each region corresponding to the depletion mode and the enhancement mode transistors, respectively. Thereafter, diffusion ions are implanted into each exposed region, thereby obtaining one depletion mode transistor and one enhancement mode transistor. The second method begins with exposing whole regions corresponding to the depletion mode and the enhancement mode transistors. Thereafter, the diffusion ions are implanted, thereby obtaining the depletion mode transistor. Thereafter, a second ion implantation for compensation is carried out for forming the enhancement transistors while only the region corresponding to the enhancement mode transistors is exposed.

In comparison with the prior art, the first active area of the FeRAM device in accordance with the present invention, incorporating therein the depletion mode transistor, is used for the bit line so that it is unnecessary to form a bit line contact in each memory cell. Therefore, a required area for forming the bit line contact can be reduced and further, it is possible to implement the device with high integration. In addition, since the bit line is parallel with the plate line, it is possible to remove a space for a cell plate driver and to reduce a word line delay.

While the present invention has been described with respect to the particular embodiments, it will be apparent to those skilled in the art that various changes and modifications may be made without departing from the scope of the invention as defined in the following claims.

What is claimed is:

1. A ferroelectric memory cell for use in a ferroelectric random access memory (FeRAM) device, the ferroelectric memory cell comprising:
a first active area incorporating therein a gate of a depletion mode transistor;
a second active area adjacent to the first active area and incorporating therein a gate of an enhancement mode transistor;
a word line coupled to the gate of the depletion mode transistor and the gate of the enhancement mode transistor; and
a ferroelectric capacitor coupled to a drain of the enhancement mode transistor, for storing data.

2. The ferroelectric memory cell as recited in claim 1, wherein the first active area of the memory cell is coupled to first active areas of neighboring memory cells, thereby forming a bit line.

3. The ferroelectric memory cell as recited in claim 2, wherein the bit line is parallel with a cell plate line of the ferroelectric capacitor.

4. The ferroelectric memory cell as recited in claim 1, wherein the first and the second active areas are n-types.

5. A ferroelectric random access memory (FeRAM) device including a plurality of ferroelectric memory cells, comprising:
first active areas incorporating therein gates of depletion mode transistors;
second active areas adjacent to the first active areas incorporating therein gates of enhancement mode transistors;
word lines coupled to the gates of the depletion mode transistors and the gates of the enhancement mode transistors; and
ferroelectric capacitors coupled to drains of the enhancement mode transistors, for storing data.

6. The ferroelectric memory device as recited in claim 5, wherein said first active areas are coupled to each other, thereby forming a bit line.

7. The ferroelectric memory device as recited in claim 6, wherein the bit line is parallel with a cell plate line of the ferroelectric capacitors.

8. The ferroelectric memory device as recited in claim 5, wherein the first and the second active areas are n-types.

9. The ferroelectric memory device as recited in claim 6, further comprising a sense amplifier for sensing and amplifying data applied to the bit line to generate an amplified signal.
